(19) United States
(12) Patent Application Publication
(10) Pub. No.: US 2025/0233571 A1
(43) Pub. Date: Jul. 17, 2025

(54) RF FILTER TOPOLOGY FOR SUBSTRATE SUPPORT ASSEMBLY

(71) Applicant: Applied Materials, Inc., Santa Clara, CA (US)

(72) Inventors: Yue GUO, Redwood City, CA (US); Kartik RAMASWAMY, San Jose, CA (US); Carlaton WONG, Sunnyvale, CA (US); Kenneth SCHATZ, Santa Clara, CA (US); Kiril KIRKOV, Santa Clara, CA (US)

(21) Appl. No.: 18/415,506

(22) Filed: Jan. 17, 2024

(51) Int. Cl. H03H 7/01; H01J 37/32

(52) U.S. Cl. CPC H03H 7/0115; H01J 37/32715; H01J 2237/2007

(57) ABSTRACT

Described herewith are an RF filter assembly for processing a coupled RF power originated from a substrate support assembly of a processing chamber, a chucking circuit for the substrate support assembly, and a method for processing the coupled RF power. The RF filter assembly includes a compensation circuit connected to an electrode of the substrate support assembly and configured to receive the coupled RF power and reduce a reflection of the coupled RF power back to the substrate support assembly; and an RF filter block configured to receive signals processed by the compensation circuit and comprising a plurality of RF filters configured to filter out predetermined frequencies of the coupled RF power. The chucking circuit includes the RF filter assembly. The method includes process and operations of the RF filter assembly.

### FIELD

Embodiments described herein generally relate to a RF filter topology for a substrate support assembly and a plasma processing chambers containing the substrate support assembly.

### BACKGROUND

### Description of the Related Art

Current substrate processing by plasma includes controlling dimension uniformity during plasma deposition and/or etch. The temperature of a substrate during plasma processing is a major factor that affects the dimension uniformity. A substrate support assembly is generally used to support and heat a substrate during processing. Thus, the amount of heat provided to the substrate support assembly needs to be controlled to maintain the temperature of the substrate within a desired range.

The substrate support assembly includes several electrodes: a power electrode for supplying an RF voltage to energize a process gas, a chucking electrode for supplying a DC voltage to chuck a substrate, and a heating electrode for supplying electric current to heat the substrate. Although each electrode is disposed in a respective circuit, capacitive couplings can occur among the several electrodes because they are placed in close proximity to each other in the substrate support assembly. The capacitive couplings can generate a coupled RF power in the chucking and/or heating circuits. These coupled RF powers can not only create safety issues but also cause unwanted damage to electrical and hardware components in the chucking and heating circuits. To mitigate the safety issue and damages to other electrical components, RF filters have been included in the circuits. But, when these additional RF filter blocks are added, the substrate support assembly may experience undesired temperature fluctuations.

Therefore, there is a need for an improved RF filter topology for a substrate support assembly.

### SUMMARY

Described herein is a RF filter assembly for blocking unwanted RF signals and noises, including a coupled RF power coupled through a substrate support assembly of a processing chamber, such as a chucking circuit or a heating circuit disposed within the substrate support assembly. A processing method of the RF filter assembly is also described. The RF filter assembly includes a compensation circuit connected to an electrode of the substrate support assembly and configured to block a coupled RF power coupled through circuits containing the electrode, such as a DC circuit of the chucking electrode or an AC circuit of the heating electrodes. The RF filter assembly includes at least one RF filter configuration (such as a low pass filter, a band-stop filter or any other suitable filters) configured to filter out predetermined frequencies of the coupled RF power. In an example, an RF filter assembly includes a compensation circuit comprising a first input configured to receive a coupled RF power and reduce the coupled RF power back through the first input; and an RF filter block comprising a second input configured to receive signals processed by the compensation circuit and comprising one or more RF filters configured to filter out predetermined frequencies of the coupled RF power.

The chucking circuit for a substrate support assembly of a processing chamber includes a chucking electrode coupled with an electric box. The electric box includes a compensation circuit connected an electrode of the substrate support assembly and configured to receive a coupled RF power and reduce the coupled RF power back to the substrate support assembly. The electric box further includes an RF filter block configured to receive signals processed by the compensation circuit and including one or more RF filters, such as RF low pass or band-stop filters, configured to filter out predetermined frequencies of the coupled RF power.

The method for processing coupled RF power originated from a substrate support assembly of a processing chamber includes transmitting the coupled RF power from an electrode within the substrate support assembly directly to a compensation circuit. The electrode includes a chucking electrode or a heating electrode. The method further includes reducing, by the compensation circuit, the coupled RF power back to the electrode, wherein the compensation circuit comprises an inductive component connected to a first grounded capacitor, and the inductive component comprises an inductor, a segment of a transmission line, or a combination of an inductor and a segment of the transmission line. The method further includes transmitting the coupled RF power processed by the compensation circuit directly to a first RF band-stop filter configured to filter out a first frequency of the coupled RF power, the first frequency corresponding to a highest frequency of an RF signal that generates the coupled RF power. The method further includes transmitting an output of the first RF band-stop filter to a second RF band-stop filter configured to filter a second frequency of the coupled RF power, the second frequency corresponding to a lowest frequency of the RF signal that generates the coupled RF power; and coupling the second RF band-stop filter with a high voltage module.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic cross-sectional view of an example of a processing chamber, according to one embodiment.

FIG. 2 illustrates a schematic cross-sectional view of an example of a substrate support assembly, according to one embodiment.

FIG. 3 illustrates a schematic circuit diagram of a chucking circuit, according to an embodiment.

FIG. 4 illustrates a detailed connection among electrical components of an exemplary chucking circuit, according to an embodiment of the present application.

FIG. 5a illustrates a detailed connection among electrical components of a compensation circuit, according to an embodiment.

FIG. 5b illustrates a detailed connection among electrical components of a compensation circuit, according to another embodiment.

FIG. 6a illustrates a schematic perspective view of an electric box containing the RF filter assembly of a chucking circuit, according to an embodiment.

FIG. 6b illustrates a schematic top view of the electric box containing the RF filter assembly of a chucking circuit, according to an embodiment.

FIG. 6c illustrates a schematic cross-sectional view of the electric box containing the RF filter assembly of a chucking circuit, according to an embodiment.

FIG. 7 illustrates a method for processing a coupled RF power transmitted by an electrode of a processing chamber, according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein include an RF filter topology for a substrate support assembly. The substrate support assembly is disposed within a processing chamber configured to process a substrate with plasma. The RF filter topology may be disposed in any circuit that may see a coupled RF power, such as the chucking circuit and/or the heater circuit. The RF filter topology includes a plurality of RF filters configured to filter out predetermined frequencies of the coupled RF power. For example, the coupled RF power may include a first low frequency of about 100 KHz to 13.56 MHz and a second high frequency of about 13.56 MHz to 200 MHZ. These low and high frequencies correspond to the frequencies of one or more RF power sources used by a plasma generating circuit to generate and maintain plasma within the processing chamber.

The RF filter topology further includes a compensation circuit disposed between the RF filters and the coupling location that generates the coupled RF power. The coupling location may be an upper portion of the substrate support assembly, where the chucking and/or heating electrodes are disposed. For example, when RF filter topology is disposed in the chucking circuit, the compensation circuit is disposed between the RF filters and the chucking electrode. The compensation circuit is configured to block coupled RF power coupled through the chucking circuits, the heater circuits, or other DC/AC lines of the substrate support assembly. If the coupled RF power is coupled back to the coupling location, such as the chucking electrode, the coupled RF power can generate additional heat and cause the temperature of the substrate assembly support to fluctuate beyond a desired range. The compensation circuit together with the RF filter are capable of reducing the coupled RF power and provides an improved substrate support assembly to control the temperature of a substrate.

When the coupling location generating the coupled RF power is viewed as a source and RF filters are viewed as a load, the compensation circuit is configured to compensate unwanted parasitic effects along the transmission lines. The compensation circuit may be implemented by a combination of electrical components, such as an inductor, a capacitor, a resistor, and any other suitable electrical components. In an example, the inductor of the compensation circuit can also be implemented by a segment of a transmission line extending between the coupling location and the RF filters. The compensation circuit may also include a circuit element configured to pass selected RF frequencies to ground.

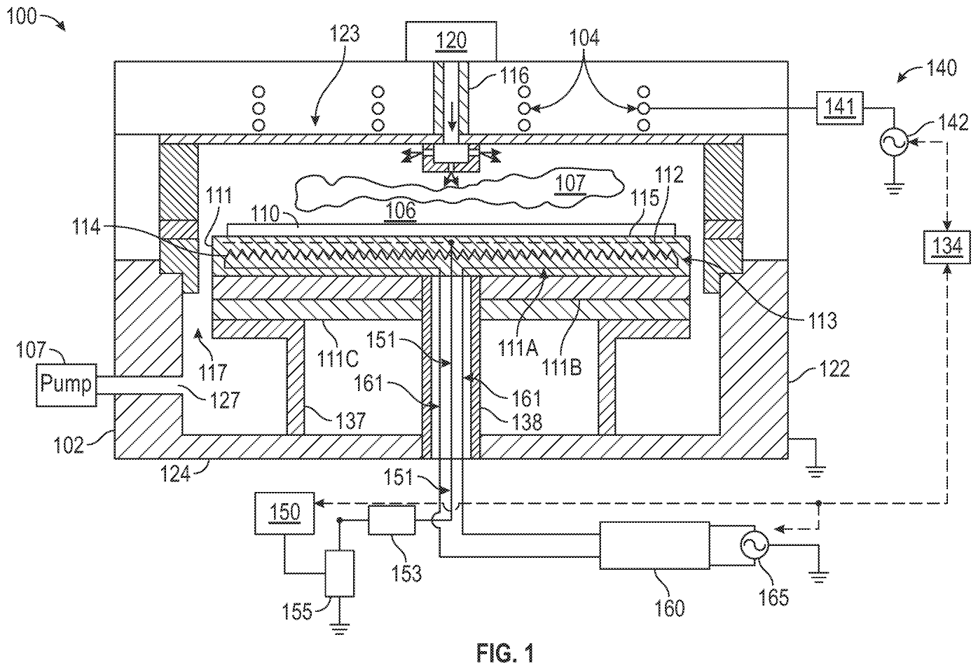

FIG. 1 illustrates a schematic cross-sectional view of a processing chamber 100 configured to perform a plasma process, according to an embodiment. In this embodiment, the processing chamber 100 is a plasma processing chamber, such as a reactive ion etch (RIE) plasma chamber. In some other embodiments, the processing chamber is a plasma-enhanced deposition chamber, for example a plasma-enhanced chemical vapor deposition (PECVD) chamber, a plasma enhanced physical vapor deposition (PEPVD) chamber, or a plasma-enhanced atomic layer deposition (PEALD) chamber. In some other embodiments, the processing chamber is a plasma treatment chamber, or a plasma based ion implant chamber, for example a plasma doping (PLAD) chamber.

As shown in FIG. 1, the processing chamber 100 further includes a chamber body 102 which includes a chamber lid 123, one or more sidewalls 122, and a chamber base 124 which define a processing volume 106. A gas inlet 116 disposed through the chamber lid 123 is used to provide one or more processing gases to the processing volume 106 from a processing gas source 120 in fluid communication therewith.

The processing chamber 100 includes a plasma power assembly 140 that includes a radio frequency (RF) power supply 142 coupled with an RF matching circuit 141. The coupled RF power supply 142 receives the power from a power generator 150 via a power regulator 134. In one embodiment, the plasma power assembly generates an inductively coupled plasma (ICP) in the processing volume 106. In other embodiments, the plasma power assembly 140 generates a capacitively coupled plasma (CCP) in the processing volume 106. The plasma power assembly 140 includes a power electrode disposed in a substrate support assembly 117. The plasma power assembly 140 may include an electrode disposed in the processing volume 106 facing a substrate support assembly 117.

The plasma power assembly 140 is configured to ignite and maintain a processing plasma 107 and is coupled to one or more inductive coils 104 disposed proximate to the chamber lid 123 outside of the processing volume 106. In an embodiment, the plasma power assembly 140 applies RF signals having a plurality of discrete frequencies. For example, the RF signals includes a first frequency wave of a relatively high basic frequency, such as about 42 MHZ, which is suitable for generating a high density plasma. At the same time, the RF signals includes a second frequency wave of a relatively low basic frequency, such as about 13 MHZ, which is suitable for drawing ions toward the substrate 110. The RF signals may also include other signals whose frequencies are integral multiples of the low basic frequency, such as about 27 MHz.

The processing volume 106 is fluidly coupled to one or more dedicated vacuum pumps 107, through a vacuum outlet 127, which maintain the processing volume 106 at sub-atmospheric conditions and evacuate processing, and/or other gases, therefrom. The substrate support assembly 117, disposed in the processing volume 106, is disposed on a support shaft 138 sealingly extending through the chamber base 124.

The substrate 110 is loaded into, and removed from, the processing volume 106 through an opening (not shown) in one of the one or more sidewalls 122. During processing, the substrate 110 is disposed on a substrate support surface 115 of a substrate support assembly 117.

The substrate support assembly 117 includes a substrate support 111 which includes an ESC substrate support 111A and a support base 111B. Typically, the ESC substrate support 111A is formed of a dielectric material, such as a bulk sintered ceramic material, such as a corrosion resistant metal oxide or metal nitride material, for example aluminum oxide (Al₂O₃), aluminum nitride (AlN), titanium oxide (TiO), titanium nitride (TiN), yttrium oxide (Y₂O₃), mixtures thereof, or combinations thereof. The ESC substrate support 111A further includes a chucking electrode 112 embedded in the dielectric material thereof.

In an embodiment, the chucking electrode 112 functions as a chucking pole used to secure (chuck) the substrate 110 to the substrate support surface 115 and to bias the substrate 110 with respect to the processing plasma 107. Typically, the chucking electrode 112 is formed of one or more electrically conductive parts, such as one or more metal meshes, foils, plates, or combinations thereof. Herein, the chucking electrode 112 is electrically coupled to a high voltage module 155 which provides a chucking voltage thereto, such as static DC voltage between about −5000 V and about 5000 V, using an electrical conductor, such as a transmission line 151. The power generator 150 supplies the power to the high voltage module 155.

In some embodiments, the ESC substrate support 111A includes a heater 113, such as a resistive heating element embedded in the dielectric material of the ESC substrate support 111A. The heater 113 generates heat through one or more heating electrodes 114 by using the AC power provided by an AC power supply 165. In one embodiment, the one or more heating electrodes 114 are spaced at a distance from the chucking electrode 112. The power generator 150 supplies power to the AC power supply 165.

According to an embodiment, the high voltage module 155 is coupled with a first RF filter assembly 153. The RF filter assembly 153 is disposed between the high voltage module 155 and the chucking electrode 112. In an embodiment, the RF filter assembly 153 is configured to prevent a coupled RF power from flowing into the high voltage module 155. In another embodiment, the RF filter assembly 153 is configured to reduce the coupled RF power from being reflected back to the chucking electrode 112. The coupled RF power is cause by the capacitive coupling between the chucking electrode 112 and the heating electrode 113 and/or the RF coil 104.

To filter out the coupled RF power, the RF filter assembly 153 includes a plurality of RF filters, such as band-stop filters, whose frequencies corresponds to frequencies of power signals supplied by the plasma power assembly 140 to generate plasma and/or power signals supplied by the AC power supply 165 to generate heat. Other filters, such as low pass filters, may also be included depending on the frequencies in the power signals.

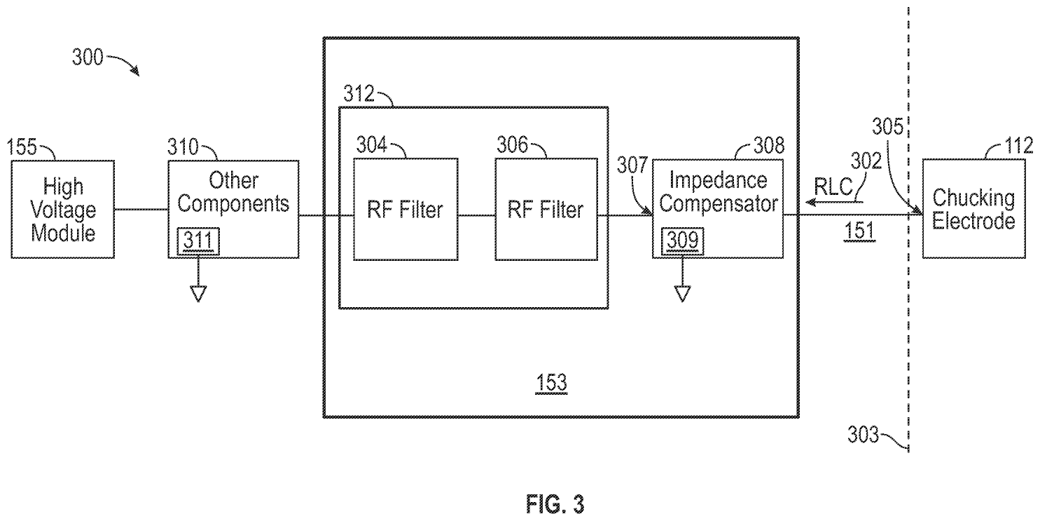

According to an embodiment, the RF filter assembly 153 includes a compensation circuit 308 (shown in FIG. 3) configured to reduce signal reflection from the RF filter assembly 153 to the substrate support assembly 117. Signal reflected from the RF filters back to the substrate support assembly 117 may receive by the chucking electrode 112 and function as additional heating current to the substrate support assembly 117. The reflected coupled RF power can cause undesired temperature fluctuations, which can be particularly problematic when a large current is provided by the plasma power assembly 140 to generate and maintain the plasma 107.

As shown in FIG. 1, the chucking electrode 112 is coupled with other electric components, such as the high voltage module 155, the RF filter assembly 135, and any other electrical components. Without any impedance matching between the chuck electrode 112 and the other electric components, a certain amount of the coupled RF power generated by the chucking electrode 112 will be coupled back to the coupling location, where the chucking electrode 112 is disposed. The compensation circuit 308 is configured to reduce the differences between the impedance of the source and the impedance of the load, thus reducing a reflection coefficient between the source and a load. In this way, the amount of the coupled RF power that is reflected from the load back to the source, such as the chucking electrode 112, can be reduced. The compensation circuit 308 provides improved controlling of unwanted heating at the substrate support assembly 117. The configuration of the RF filter assembly 153 will be described detail later in this application.

In one embodiment, an RF filter assembly 160 is disposed between the AC power supply 165 and the one or more heating electrodes 114. Similarly with the RF filter assembly 153, the filter assembly 160 further includes a plurality of RF filters configured to prevent any coupled RF power from flowing into the AC power supply 165. The filter assembly 160 further includes a compensation circuit configured to compensate parasitic effects and reduce a coupled RF power from being coupled back to the heating electrodes 114.

The support base 111B is electrically isolated from the chamber base 124 by an insulator plate 111C, and a ground plate 137 that is interposed between the insulator plate 111C and the chamber base 124. In some embodiments, the support base 111B includes one or more cooling channels (not shown) disposed therein that are fluidly coupled to, and in fluid communication with, a coolant source (not shown), such as a refrigerant source or water source having relatively high electrical resistance. Herein, the support base 111B is formed of a corrosion resistant thermally conductive material, such as a corrosion resistant metal, for example aluminum, aluminum alloy, or stainless steel and is coupled to the substrate support with an adhesive or by mechanical means.

The processing chamber 100 further includes a system controller 134. The system controller 134 herein includes a central processing unit (CPU), a memory, and support circuits. The system controller 134 is used to control the process sequence used to process the substrate 110. A program (or computer instructions) readable by the system controller 134 determines which tasks are performable by the components in the processing chamber 100. The program will include instructions that are used to control the various hardware and electrical components within the processing chamber 100 to perform the various process tasks and various process sequences used to implement the electrode biasing scheme described herein.

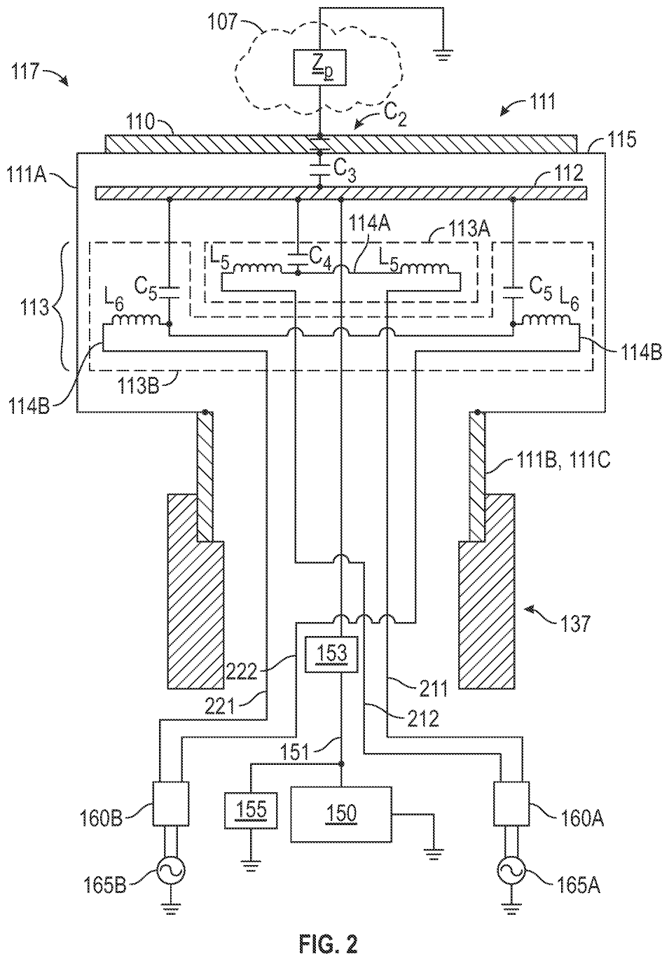

FIG. 2 is a schematic side cross-sectional view of portions of the substrate support assembly 117. The heater 113, which is embedded within ESC substrate support 111A, may include a plurality of heating zones, such as an inner heater zone 113A that includes a first heating electrode 114A and outer heater zone 113B that includes a second heating electrode 114B. A first side of the first heating electrode 114A is coupled to a first conductive lead 211 and a second side of the first heating electrode 114A is coupled to a second conductive lead 212.

The power generator 150 is configured to provide nano-second DC pulses, or in some configurations coupled RF power, to the chucking electrode 112 which is capacitively coupled to the plasma 107 through a plurality of series capacitances that can include an ESC capacitance C₃ and a substrate capacitance C₂. The plasma 107 will generally have an impedance Zₚ that includes a series of complex impedances due to the formed plasma and plasma sheaths formed at the chamber walls and over the substrate 110. The dielectric layer in the electrostatic chuck and the substrate 110 separate the chucking electrode 112 from the plasma 107 and are represented in the circuits in FIG. 2 by capacitors C₃ and C₂. The chucking electrode 112 will also be capacitively coupled to the first heating electrode 114A and second heating electrode 114B, as represented by the capacitances C₄ and C₅ in FIG. 2, respectively. The capacitive coupling among the chucking electrode 112, the heating electrodes 114, and the plasma 107 can cause a coupled RF power in circuits that contain the chucking electrode 112 and the heating electrodes 114, respectively.

FIG. 3 is a schematic block diagram of a chucking circuit 300 according to an embodiment. The chucking circuit 300 includes the chucking electrode 112, the RF filter assembly 153, the high voltage module 155, and other optional electric components 310. The chucking electrode 112 is disposed in the substrate support assembly 117, which is disposed inside the processing chamber 100. The RF filter assembly 153, the high voltage module 155, and other optional electric components are disposed outside the processing chamber 100. The chucking electrode 112 couples with the RF filter assembly 153 via the transmission line 151. A chamber wall 303 separates the RF filter assembly 153 from the chucking electrode 112. The RF filter assembly 153 includes the compensation circuit 308 and an RF filter block 312 including a plurality of RF filters 304 and 306.

Within the RF filter assembly 153, the coupled RF power 302 first reaches the compensation circuit 308, which is configured to reduce the impedance difference between the chucking electrode 112 and the RF filter block 312. The compensation circuit 308 includes an input 305 that receives the coupled RF power 302 and an output 307 that outputs the processed coupled RF power to the first RF filter 306. The compensation circuit 308 may also include a grounded electrical component 309, which allows selected RF frequencies to go to the ground. The compensation circuit 308 outputs processed signals to the RF filter block 312. In an embodiment, the RF filter block 312 includes one or more RF filters, such as a RF low pass filter, a RF band-gap filter, or any other suitable RF filters. As shown in FIG. 3, two RF band-stop filters 304, 306 are included in the RF filter block 312 and configured to sequentially filter out two different frequency signals (13 MHz and 42 MHz) in the coupled RF power 302. The chucking electrode 112, the compensation circuit, the RF band-stop filter 306, and RF band-stop filter 304 are serially connected.

The chucking electrode 112 generates the coupled RF power 302 due to the capacitive coupling with the plasma 107 or the heating electrodes 114. The coupled RF power 302 includes RF signals of the same frequencies as the frequencies of the RF power assembly 140 and/or the heating power supply 165. The coupled RF power 302 may also include other frequencies. In an embodiment, the coupled RF power 302 includes signals of about 13 MHz and 42 MHz. The coupled RF power 302 flows from the chucking electrode 112 directly to the input 305 of the RF filter assembly 153. In one embodiment, the RF filter assembly 153 includes at least one RF filter 306. In another embodiment, the RF filter assembly 153 includes a plurality of RF filters 304 and 306. The RF filter may include a RF low pass filter or a RF band-stop filter or any other suitable filters. Each of the RF filters is configured to filter out signals of a single frequency. For example, the RF filter assembly 135 includes a first RF band-stop filter 306 configured to filter out signals of about 42 MHz and a second RF filter 304 configured to filter out signals of about 13 MHz. The plurality of RF filters 304 and 306 are arranged to filter out the coupled RF power from a highest frequency to a lowest frequency. As shown in FIG. 3, the coupled RF power 302 reaches the first RF filter 306 first, which is configured to filter out the signals of the highest frequency, such as 42 MHz. The coupled RF power 302 exits the RF filter assembly 153 via the second RF filter 304, which is configured to filter out the signals of the lowest frequency, such as 13 MHz.

Other frequencies of the coupled RF power 302 may be further filtered out by other electrical components 310, which is serially connected to the RF filter assembly 153. The other electrical components 310 may include a low pass filter or any other suitable components. The other electrical components 310 may include a grounded electrical component 311.

The chucking circuit 300 as shown in FIG. 3 reduces reflection of the coupled RF power 302 by the RF filter block 312. Thus, the chucking circuit 300 provides an improved control of heating the substrate support assembly 117. Similar with the chucking circuit 300, the heating circuit may be configured to include an impedance compensation block between the heating electrodes 114 and other RF filters.

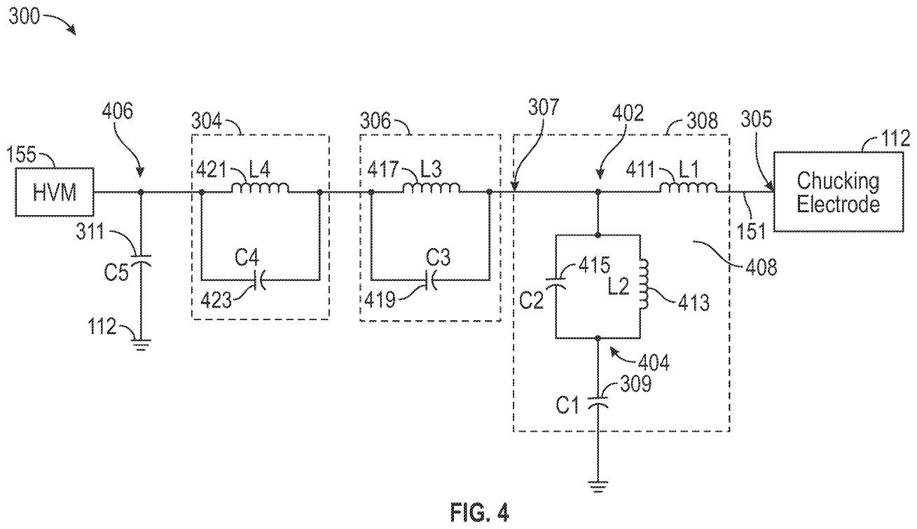

FIG. 4 illustrates a detailed connection of electric components of an exemplary chucking circuit 300, according to an embodiment of the present application. The coupled RF power 302 flows from the chucking electrode 112 toward other electrical components of the chucking circuit 300, such as the high voltage module 155. The compensation circuit 308 is disposed outside the processing chamber 110. The compensation circuit 308 is disposed between the chucking electrode 112 and other components of the chucking circuit, such as the RF band-stop filters 306, 304 and the high voltage module 155.

In an embodiment, the compensation circuit 308 includes an inductive component L1 411, a tank circuit 408, and a capacitor C1 309. The inductive component L1 411 is serially connected to the chucking electrode 112 via the input 305 and outputs processed signals to the first RF band-stop filter 306 and the tank circuit 408 via a node 402. The tank circuit 408 and the RF band-stop filter 306 are connected in parallel. The tank circuit 408 may be a parallel LC circuit including an inductor L2 413 and a capacitor C2 415. The tank circuit 408 is serially connected to another capacitor C1 309, which is grounded. According to an embodiment, the inductive component L1 411 is an inductor. According to an embodiment, a segment of the transmission line 151 may be added in series with an inductor or in replacement of the inductive component L1 411. In this way, the usage of additional lumped electrical components can be avoided.

The first RF band-stop filter 306 may be a parallel LC circuit configured to filter out the highest frequency in the coupled RF power 302, such as about 42 MHz. The RF band-stop filter 306 includes an inductor L3 417 and a capacitor C3 419.

The second RF band-stop filter 304 may be a parallel LC circuit configured to filter out the lowest frequency in the coupled RF power 302, such as 13 MHZ. The RF band-stop filter 304 includes an inductor L4 421 and a capacitor C4 423. The first RF band-stop filter 306 and the second band-stop RF filter 304 are serially connected.

The second RF band-stop filter 304 connects with the high voltage module 155 and a capacitor C5 311 via a node 406. The capacitor C5 311 is grounded. The capacitor C5 311 is connected to the high voltage module 155 in parallel. In an embodiment, the capacitor C5 311 functions as a shunt capacitor.

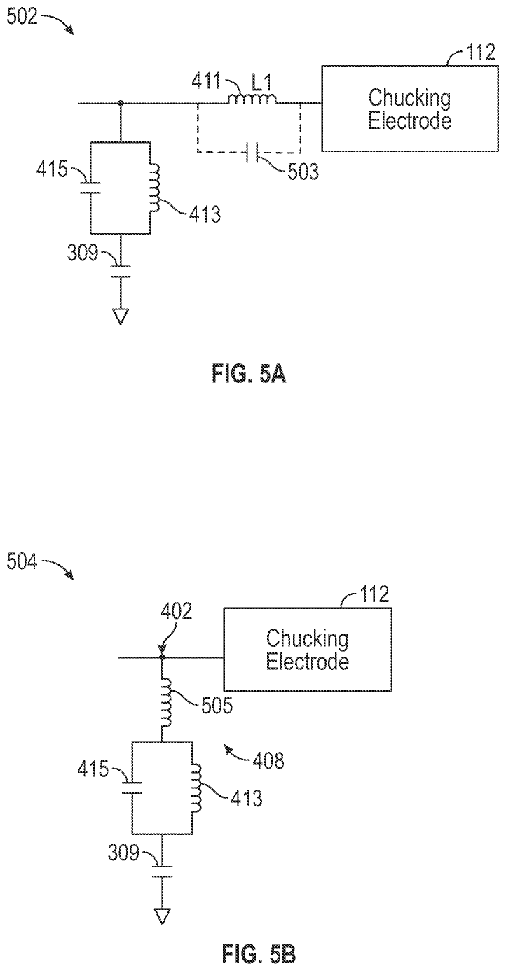

FIG. 5a illustrates a circuit diagram of a compensation circuit 502, according to an embodiment. Comparing to the compensation circuit 308 shown in FIG. 4, the compensation circuit 502 further includes a capacitor 503 that is connected to the inductive component L1 411 in parallel.

FIG. 5b illustrates a circuit diagram of a compensation circuit 504, according to an embodiment. Comparing to the compensation circuit 308 shown in FIG. 4, the compensation circuit 504 removes the inductive component L1 411 and includes another inductive component 505 between the node 402 and the tank circuit 408. The inductive component 505 is serially connected to the tank circuit 408. The inductive component 505 may be an inductor, a segment of a transmission line, or the combination of an inductor and a segment of a transmission line.

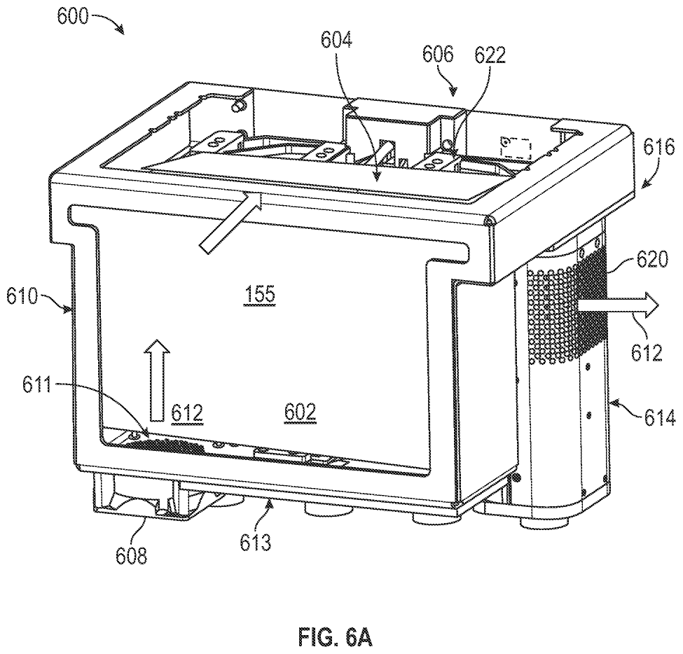

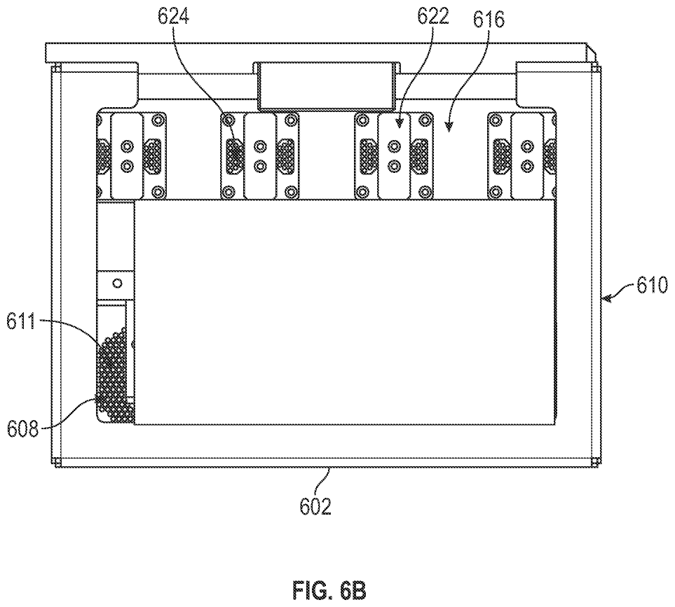

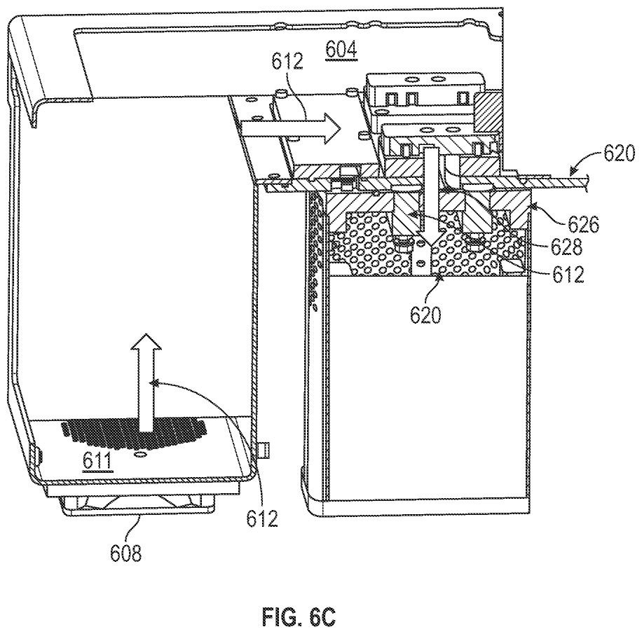

FIG. 6a illustrates a schematic perspective view of an electric box 600 containing the RF filter assembly 153 of the chucking circuit 300 according to an embodiment. FIG. 6b illustrates a schematic top view of the electric box 600 containing the RF filter assembly 153 of the chucking circuit 300 according to an embodiment. FIG. 6c illustrates a schematic cross-sectional view of the electric box 600 containing the RF filter assembly 153 of the chucking circuit 300 according to an embodiment.

As shown in FIG. 6a, the electric box 600 includes a housing 610 that encloses internal parts. The housing 610 forms a first chamber 602 that contains the high voltage module 155. The electric box 600 further includes a plurality of RF components 614 coupled with the housing 610 via a bracket 616. According to an embodiment, the plurality of RF components 614 include a compensation circuit 308, a first RF band-stop filter 306, a second RF-band stop filter 304, and an optional electrical component 310 as described in the present application. The housing 610 further forms an upper chamber 604 that contains the bracket 616 and a plurality of connectors 622 coupled with the plurality of RF components 614.

The electric box 600 includes a fan 608 that forces air 612 into the housing 610 via a chamber vent 611. The fan 608 and the chamber vent 611 are disposed at a bottom wall 613 that is facing the upper chamber 604. The fan 608 forces the air 612 into the first chamber 602, then into the upper chamber 604, and then into the RF components 614. The air 612 exits the RF components 614 via a plurality of vents 620 formed on the housings of the RF components 614. The air 612 transfer heat out of the electric box 600 and the RF components 614.

As shown in FIG. 6b, the bracket 616 includes a plurality of connectors 622, each of which couples with one of the plurality of RF components 614. The bracket 616 further includes a plurality of vents 624 disposed adjacent to the connectors. According to an embodiment, each of the plurality of RF components 614 includes a cap 626 (shown in FIG. 6c). The cap 626 includes a vent 628 (shown in FIG. 6c), whose location and shape correspond to the vent 624 in the bracket 616. The alignment between the vent 628 and the vent 624 allows the air 612 to flow from the upper chamber 604 to the RF components 614 with reduced resistance.

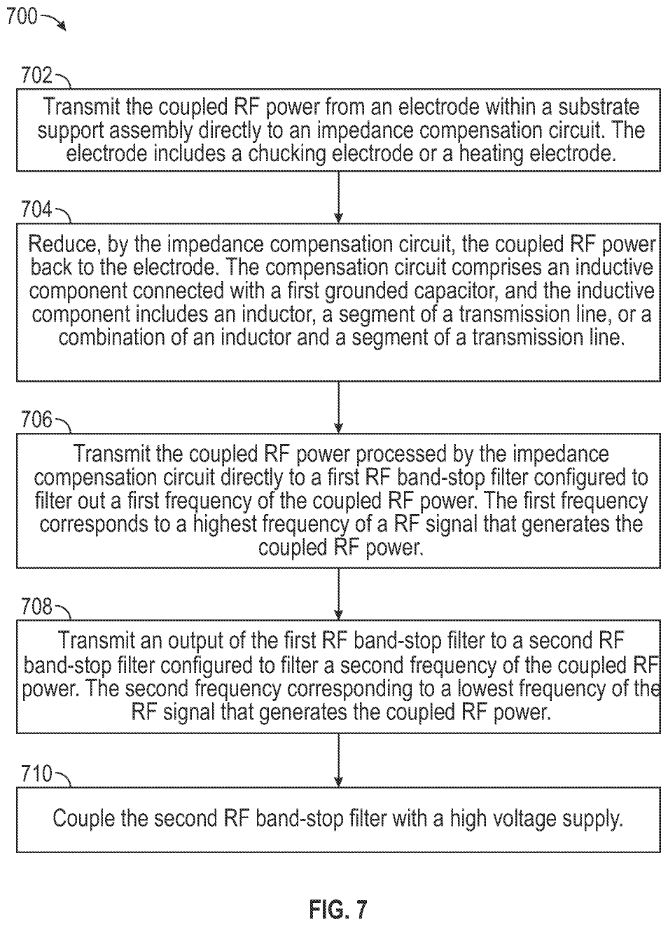

FIG. 7 illustrates a method 700 for processing a coupled RF power originated from a substrate support assembly of a processing chamber, according to an embodiment. At operation 702, the substrate support assembly 117 generates the coupled RF power due to the capacitive coupling among the chucking electrode, the heating electrode, and the power electrode of the plasma. The coupled RF power is transmitted from an electrode, such as the chucking electrode or the heating electrode, directly to a compensation circuit. At operation 704, the compensation circuit reduces the coupled RF power back to the electrode, the compensation circuit including an inductive component connected to a first grounded capacitor, and the inductive component may include an inductor, a segment of a transmission line, or a combination of an inductor and a segment of the transmission line. At operation 706, the coupled RF power processed by the compensation circuit is transmitted directly to a first RF band-stop filter configured to filter out a first frequency of the coupled RF power, the first frequency corresponding to a highest frequency of an RF signal that generates the coupled RF power. At operation 708, an output of the first RF band-stop filter is transmitted to a second RF band-stop filter configured to filter a second frequency of the coupled RF power, the second frequency corresponding to a lowest frequency of the RF signal that generates the coupled RF power. At operation 710, the second RF band-stop filter is coupled with a high voltage supply. The method 700 may include other processes and operations as described in the present application.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

1. An RF filter assembly, comprising:
a compensation circuit comprising a first input configured to receive a coupled RF power and reduce the coupled RF power back through the first input; and
an RF filter block comprising a second input configured to receive signals processed by the compensation circuit and comprising one or more RF filters configured to filter out predetermined frequencies of the coupled RF power.

2. The RF filter assembly of claim 1, wherein the compensative circuit comprises an inductive component formed by an inductor, a segment of a transmission line, or a combination of an inductor and a segment of a transmission line.

3. The RF filter assembly of claim 2, wherein the inductive component is connected to the first input, and the compensation circuit further comprises a first capacitor connected to the inductive component and grounded.

4. The RF filter assembly of claim 3, wherein the compensation circuit comprises a first tank circuit that is connected to the inductive component and the first capacitor, and the first tank circuit is connected to the RF filter block in parallel.

5. The RF filter assembly of claim 2, wherein the inductive component is formed by a segment of a transmission line of the compensation circuit.

6. The RF filter assembly of claim 5, wherein the compensation circuit further comprises a second capacitor coupled with the inductive component in parallel to form a second tank circuit.

7. The RF filter assembly of claim 1, wherein the first input is connected to a heating electrode or a chucking electrode of a substrate support assembly.

8. The RF filter assembly of claim 1, wherein the RF filter block comprises a plurality of serially connected RF filters configured to filter out predetermined frequencies from a highest one to a lowest one.

9. The RF filter assembly of claim 1, further comprising a grounded shunt capacitor connected to the RF filter block.

10. The RF filter assembly of claim 9, wherein the RF filter assembly is connected to a high voltage module, and the ground shunt capacitor is connected to the high voltage module in parallel.

11. A chucking circuit for a substrate support assembly of a processing chamber, comprising:
a chucking electrode coupled with an electric box,
the electric box comprising:
a compensation circuit connected to the chucking electrode of the substrate support assembly and configured to receive a coupled RF power from an input and reduce a reflection of the coupled RF power back through the input; and
an RF filter block configured to receive signals processed by the compensation circuit and comprising a plurality of RF filters configured to filter out predetermined frequencies of the signals processed by the compensation circuit.

12. The chucking circuit of claim 11, wherein the compensation circuit comprises an inductive component formed by an inductor, a transmission line, or a combination of an inductor and a transmission line.

13. The chucking circuit of claim 12, wherein the inductive component is connected to the input, and the compensation circuit further comprises a first capacitor connected to the inductive component and grounded.

14. The chucking circuit of claim 13, wherein the compensation circuit comprises a first tank circuit that is connected to the inductive component and the first capacitor, and the first tank circuit is connected to the RF filter block in parallel.

15. The chucking circuit of claim 12, wherein the inductive component is formed by a segment of a transmission line of the compensation circuit.

16. The chucking circuit of claim 15, wherein the compensation circuit further comprises a second capacitor coupled with the inductive component in parallel to form a second tank circuit.

17. The chucking circuit of claim 15, wherein the input is connected to the chucking electrode.

18. The chucking circuit of claim 11, wherein the RF filter block comprises a plurality of serially connected RF filters configured to filter out predetermined frequencies from a highest one to a lowest one.

19. The chucking circuit of claim 11, wherein the electric box comprises a first housing enclosing a high voltage module, a second housing enclosing the compensation circuit, and a bracket coupling the first housing and second housing, the bracket and the second housing comprising a plurality of vents that allow air to flow from the first housing to the second housing.

20. A method for processing a coupled RF power originated from a substrate support assembly of a processing chamber, comprising:
transmitting the coupled RF power from an electrode within the substrate support assembly directly to a compensation circuit, the electrode comprising a chucking electrode or a heating electrode;
reducing, by the compensation circuit, the coupled RF power back to the electrode, wherein the compensation circuit comprises an inductive component connected to a first grounded capacitor, and the inductive component comprises an inductor, a segment of a transmission line, or a combination of an inductor and a segment of the transmission line;
transmitting the coupled RF power processed by the compensation circuit directly to a first RF band-stop filter configured to filter out a first frequency of the coupled RF power, the first frequency corresponding to a highest frequency of an RF signal that generates the coupled RF power;
transmitting an output of the first RF band-stop filter to a second RF band-stop filter configured to filter a second frequency of the coupled RF power, the second frequency corresponding to a lowest frequency of the RF signal that generates the coupled RF power; and
coupling the second RF band-stop filter with a high voltage module.
